(19) United States
(12) Patent Application Publication
(10) Pub. No.: US 2013/0075126 A1
(43) Pub. Date: Mar. 28, 2013

(54) Laser Bleached Marking of Dyed Anodization

(71) Applicants: Michael S. Nashner, San Jose, CA (US); John Thomton, Los Gatos, CA (US); Malcolm Early, Menlo Park, CA (US); Emery A. Sanford, San Francisco, CA (US); Matthew S. Scott, Sunnyvale, CA (US); Bradley Sewell, West Alexandria, OH (US); Kaylie Liu, ShenZhen (CN); Ronald J. Moller, Los Gatos, CA (US); Jody Akana, San Francisco, CA (US)

(72) Inventors: Michael S. Nashner, San Jose, CA (US); John Thomton, Los Gatos, CA (US); Malcolm Early, Menlo Park, CA (US); Emery A. Sanford, San Francisco, CA (US); Matthew S. Scott, Sunnyvale, CA (US); Bradley Sewell, West Alexandria, OH (US); Kaylie Liu, ShenZhen (CN); Ronald J. Moller, Los Gatos, CA (US); Jody Akana, San Francisco, CA (US)

(21) Appl. No.: 13/246,041

(22) Filed: Sep. 27, 2011

(51) Int. Cl. H05K 5/04; B23K 26/00

(52) U.S. Cl. 174/50; 219/121.85

(57) ABSTRACT

Techniques or processes for providing markings on products are disclosed. In one embodiment, the products have housings and the markings are to be provided on the housings. For example, a housing for a particular product can include an outer housing surface and the markings can be provided on the outer housing surface so as to be visible from the outside of the housing. The surface of the housing is able to be anodized and dyed, and the markings of the surface are able to be bleached markings of dyed anodization.

### BACKGROUND OF THE INVENTION

Consumer products, such as electronic devices, may be marked for notifying users of various kinds of different information. For example, by marking electronic devices with a supplier's brand, consumers can identify the electronic devices as sourced from the supplier. Distinctive brand marking can be helpful in brand identification.

Printing or stamping process using ink pigments may be used for such marking. Although conventional ink pigment printing and stamping is useful for many situations, such techniques can be inadequate in the case of marking metal housings of handheld electronic devices.

There may be various reasons for using metal housings in small form factor, handheld electronic devices, such as mobile phones, portable media players and Personal Digital Assistants (PDAs). Metal housings of small form factor, handheld electronic devices may be strong, lightweight, or durable for portable use of the devices in various environments. Metal housings may be attractive for substantially providing a compact shielding solution to Electro- Magnetic Interference (EMI) problems, which may otherwise be encountered by such handheld electronic devices.

In order for marking of such metal housings to be legible and easily recognizable, the marking must be accurately and precisely formed and must be distinctive. Unfortunately, however, conventional techniques are not able to offer sufficient accuracy, precision and distinctiveness. Thus, there is a need for improved techniques to mark metal housings of products.

### SUMMARY

The invention pertains to techniques or processes for providing markings on products. In one embodiment, the products have housings and the markings are to be provided on the housings. For example, a housing for a particular product can include an outer housing surface and the markings can be provided on the outer housing surface so as to be visible from the outside of the housing. The markings provided on products can be textual and/or graphic. The markings can be formed with high resolution. The surface of the housing is able to be anodized and dyed, and the markings of the surface are able to be bleached markings of dyed anodization.

In general, the markings (also referred to as annotations or labeling) provided on products according to the invention can be textual and/or graphic. The markings can be used to provide a product (e.g., a product's housing) with certain information. The marking can, for example, be use to label the product with various information. When a marking includes text, the text can provide information concerning the product (e.g., electronic device). When a marking includes a graphic, the graphic can pertain to a brand graphic, logo, a certification mark, standards mark or an approval mark that is often associated with the product. The marking can be used for advertisements to be provided on products. The markings can also be used for customization (e.g., user customization) of a housing of a product.

The invention can be implemented in numerous ways, including as a method, system, device, or apparatus. Several embodiments of the invention are discussed below.

As an electronic device housing, one embodiment of the invention can, for example, include at least a metal structure of the electronic device housing including at least an outer portion and an inner portion. The outer portion can be anodized and the inner portion can be unanodized. A first dye can be incorporated into the outer portion and adjacent to the inner portion. Regions of the first dye can be selectively altered. The altered regions of the first dye can be laser bleached to provide predetermined marking of the electronic device housing.

As a method for marking an electronic device housing, one embodiment can, for example, include at least providing a metal structure for the electronic device housing, anodizing an outer portion of the metal structure so as to provide an anodized outer portion of the metal structure and an unanodized inner portion of the metal structure, incorporating a first dye into the outer portion and adjacent to the inner portion, and selectively altering regions of the first dye incorporated into the outer portion, wherein selectively altering comprises laser bleaching to provide predetermined marking of the electronic device housing.

As a method for marking an article, one embodiment can, for example, include at least providing a metal structure for the article, anodizing an outer portion of the metal structure so as to provide an anodized outer portion of the metal structure and an unanodized inner portion of the metal structure, incorporating a first dye and a second dye into the outer portion and adjacent to the inner portion, and sufficiently altering regions of the first dye so as to provide predetermined marking of the article.

Other aspects and advantages of the invention will become apparent from the following detailed description taken in conjunction with the accompanying drawings which illustrate, by way of example, the principles of the invention.

### BRIEF DESCRIPTION OF THE DRAWINGS

The invention will be readily understood by the following detailed description in conjunction with the accompanying drawings, wherein like reference numerals designate like structural elements, and in which:

FIG. 1 is a diagram of a marking state machine according to one embodiment of the invention.

FIG. 2 is an illustration of a metal structure having markings according to one embodiment.

FIG. 3 is a flow diagram of marking processes according to one embodiment.

FIGS. 4A-4D are diagrams illustrating marking of a metal structure according to one embodiment.

FIG. 5 is a first table illustrating exemplary laser operation parameters for marking according to one embodiment.

FIG. 6A is a diagrammatic representation of an exemplary product housing.

FIG. 6B illustrates the product housing having markings according to one exemplary embodiment.

FIG. 7 is a flow diagram of marking processes according to another embodiment.

FIG. 8 is a second table illustrating exemplary laser operation parameters for marking according to another embodiment.

FIG. 9 is a top view diagram for representatively illustrating high magnification of microcracking of anodization.

FIG. 10 is a flow diagram of a marking process according to another embodiment.

FIG. 11 illustrates the product housing having markings according to another embodiment.

### DETAILED DESCRIPTION OF EMBODIMENTS OF THE INVENTION

The invention pertains to techniques or processes for providing markings on products. In one embodiment, the products have housings and the markings are to be provided on the housings. For example, a housing for a particular product can include an outer housing surface and the markings can be provided on the outer housing surface so as to be visible from the outside of the housing. The housing can pertain to an electronic device housing. The markings provided on products can be textual and/or graphic. The markings can be formed with high resolution. The surface of the housing is able to be anodized and dyed, and the markings of the surface are able to be bleached markings of dyed anodization. Various suitable organic and/or organometallic dyes can be used,

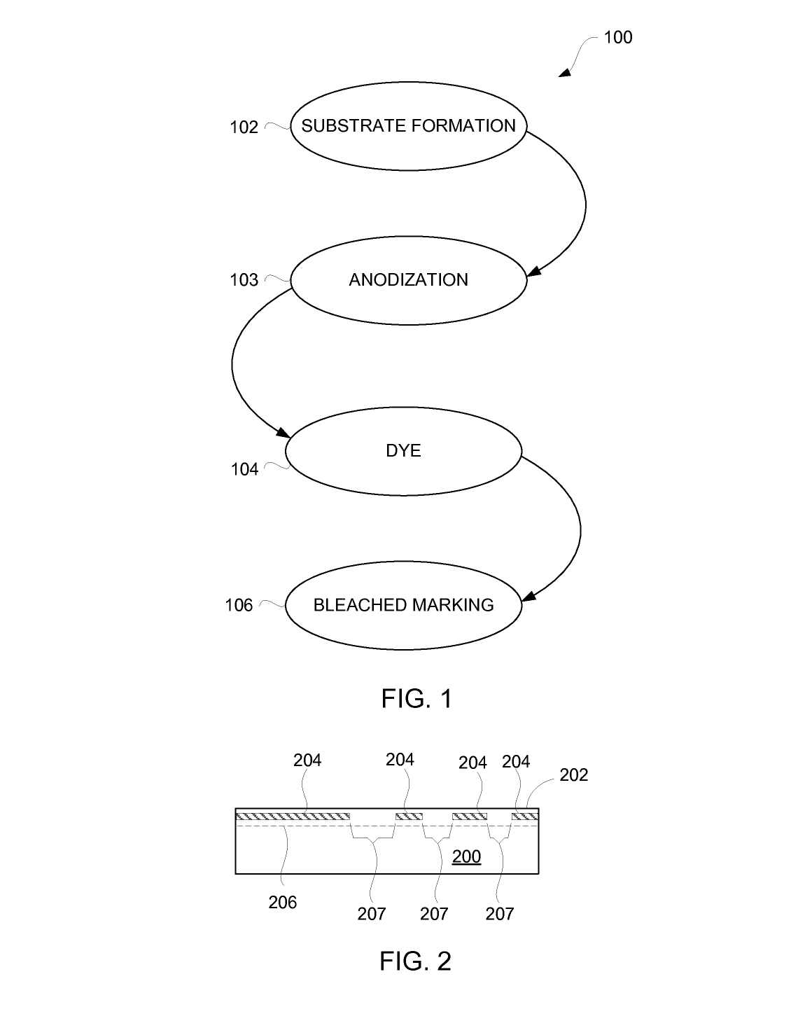

Exemplary embodiments of the invention are discussed below with reference to FIGS. 1-11. However, those skilled in the art will readily appreciate that the detailed description given herein with respect to these figures is for explanatory purposes as the invention extends beyond these limited embodiments.

FIG. 1 is a diagram of a marking state machine 100 according to one embodiment of the invention. The marking state machine 100 reflects four (4) basic states associated with marking a metal structure of an electronic device. Specifically, the marking can mark a housing of an electronic device, such as a portable electronic device.

The marking state machine 100 includes a metal structure formation state 102. At the substrate formation state 102, a metal structure can be obtained or produced. For example, the metal structure can represent at least a portion of a housing surface of an electronic device. Next, the marking state machine 100 can transition to an anodization state 103. At the anodization state 103, anodization can be produced on the metal structure. In other words, the metal structure can be anodized. Next, the marking state machine 100 can transition to a dye state 104. At the dye state 104, the anodization can be dyed. Next the marking state machine 100 can transition to a bleached marking state 106. At the bleached marking state 106, regions of the dye can be selectively altered. The altered regions of the dye can be laser bleached to provide predetermined marking of the metal structure of the electronic device housing.

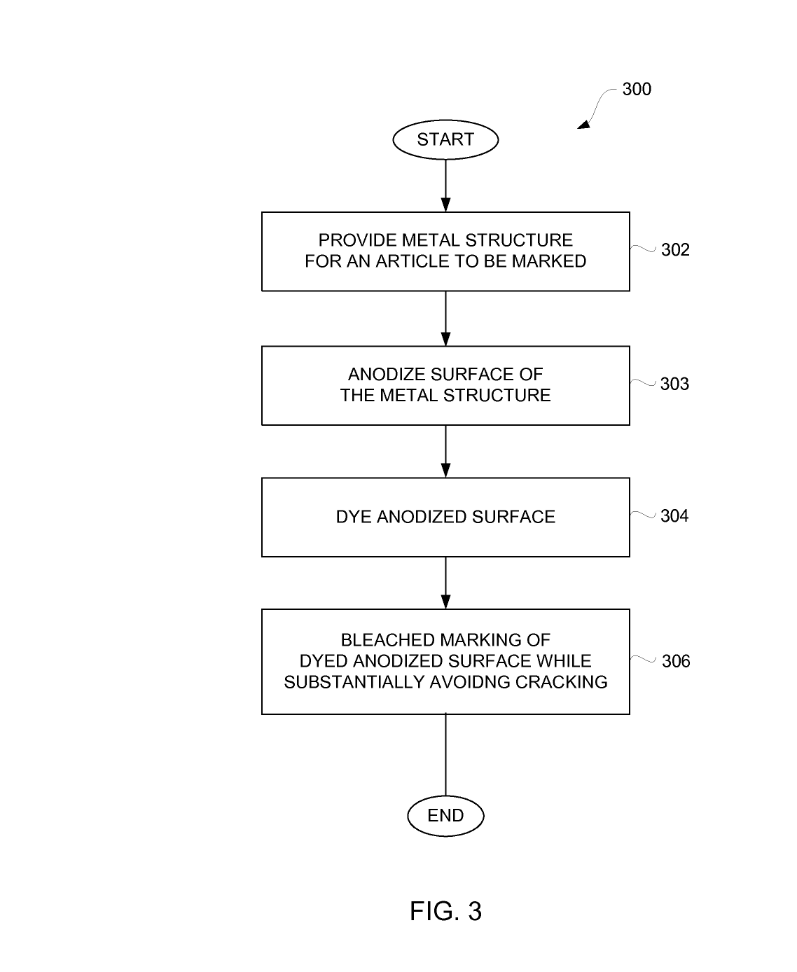

FIG. 2 is an illustration of a metal structure 200, which may comprise aluminum. The metal structure can include at least an outer portion 202 and an inner portion 206. The outer portion 202 can be anodized and the inner portion 206 can be unanodized. A dye 204 can be incorporated into the outer portion 202 and adjacent to the inner portion 206. Regions 207 of the dye can be selectively altered. The altered regions 207 of the dye can be laser bleached to provide predetermined marking of the electronic device housing. The marking techniques are particularly useful for smaller scale portable electronic devices, such as handheld electronic devices. Examples of handheld electronic devices include mobile telephones (e.g., cell phones), Personal Digital Assistants (PDAs), portable media players, remote controllers, pointing devices (e.g., computer mouse), game controllers, etc.

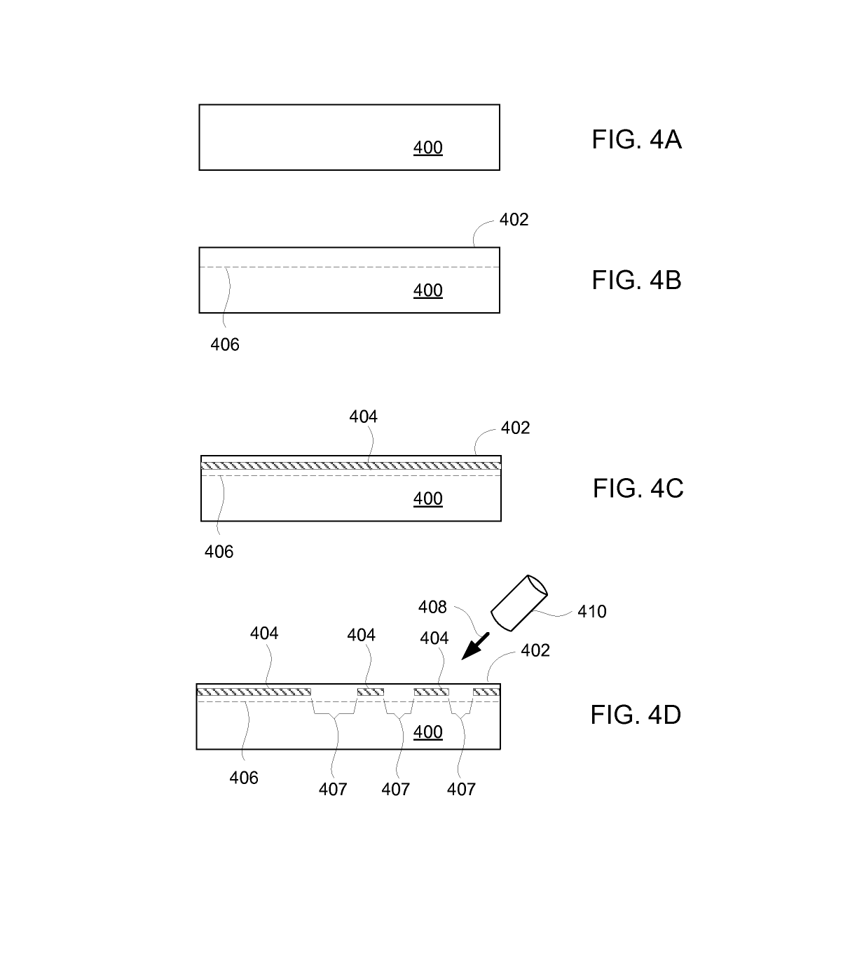

FIG. 3 is a flow diagram of a marking process 300 according to one embodiment. The marking process 300 can be performed on a metal structure of an electronic device that is to be marked. The marking process 300 is, for example, suitable for applying text or graphics to a housing (e.g., an outer housing surface) of an electronic device. The marking can be provided such that it is visible to users of the electronic device. However, the marking can be placed in various different positions, surfaces or structures of the electronic device.

The marking process can provide a metal structure for an article to be marked. The metal structure can pertain to a metal housing for an electronic device, such as a portable electronic device, to be marked. The metal structure can be formed of one metal layer. The metal structure can also be formed of multiple layers of different materials, where at least one of the multiple layers is a metal layer. The metal structure can be formed of aluminum, titanium, niobium or tantalum.

In accordance with the marking process 300 shown in FIG. 3, the process may begin with providing 302 the metal structure of the electronic device to be marked. After the metal structure has been provided 302, the surface of the metal structure may be anodized 303. Typically, the surface of the metal structure to be anodized 303 may be an outer or exposed metal surface of the metal structure. The outer or exposed surface typically may represent an exterior surface of the metal housing for the electronic device. Anodizing 303 an outer portion of the metal structure can provide an anodized outer portion of the metal structure and an unanodized inner portion of the metal structure.

Next, as shown in FIG. 3, the anodized surface of the metal structure may be dyed 304. The anodized surface of the metal structure may be porous. Accordingly, dye may be incorporated into the anodized surface by disposing dye into pores of the anodized surface. In other words, dye may be incorporated into the outer anodized portion of the metal structure and adjacent to the inner unanodized portion of the metal structure.

Dyeing may impart a rich color to the anodized surface. Since the anodized surface is porous in nature following anodization, the anodized surface may absorb a dye through its pores to impart the rich color to the anodized surface. The anodized surface may possess increased adherence capabilities for dyes, relative to metal. Beads of dye may flow into pores of the anodized surface, and adhere, so as to impart the color to the anodized surface. Dyeing may be accomplished through dipping or immersing the anodized surface into a dye solution containing a dye which will impart a desired color to the anodized surface. In some embodiments, the dye solution may be maintained at a temperature in a range between about 50 and 55 degrees Celsius. In some embodiments, the dye solution may contain a stabilizer to control the pH. Color control may be achieved by measuring the dyed anodized surface with a spectrophotometer and comparing the value against an established standard.

Next, regions of the dye incorporated into the outer anodized portion may be selectively altered. Bleached marking 306 may be used. Regions of the dye may be selectively altered so as to have an appearance that is substantially lighter than remainder unaltered regions of the dye. Selectively altered regions of the dye may be arranged in a lightness halftone pattern. Selectively altering may comprise laser bleaching 306 to provide predetermined marking of the electronic device housing. Selectively altering regions of the first dye may cause one or more textual or graphical indicia to appear on the electronic device housing.

Laser bleaching 306 may comprise scanning output of a laser over the anodized outer portion sufficiently slowly so as to substantially avoid noticeable disturbance to the anodized outer portion. Output of the laser may be scanned sufficiently slowly over the anodized outer portion so as to substantially avoid microcracking of the anodized outer portion. The laser can be an ultraviolet laser. Following the bleached marking block 306, the marking process 300 shown in FIG. 3 can end.

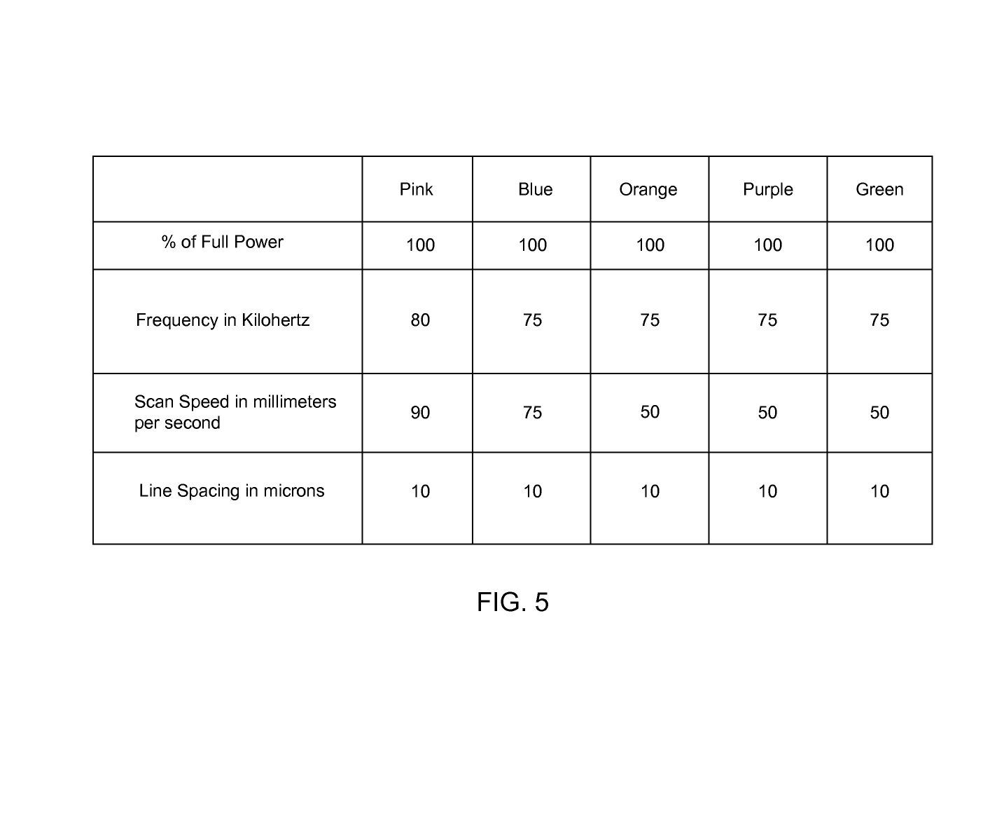

FIGS. 4A-4D are diagrams illustrating marking of a metal structure 400 according to one embodiment. In FIG. 4A, metal structure 400 is provided for marking. As examples, the metal structure 400 can be formed of aluminum, titanium, niobium or tantalum.

The surface of the metal structure 400 may be anodized. As shown in FIG. 4B anodizing an outer portion of the metal structure 400 can provide an anodized outer portion 402 of the metal structure 400 and an unanodized inner portion 406 of the metal structure 400.

The anodized outer portion 402 of the metal structure 400 may be dyed. The anodized outer portion 402 of the metal structure may be porous. Accordingly, as shown in FIG. 4C, dye 404 may be incorporated into the anodized outer portion 402 of the metal structure 400 by disposing dye 404 into pores of the anodized outer portion 402. Dye 404 may be incorporated into the outer anodized portion 402 of the metal structure 400 and adjacent to the inner unanodized portion 406 of the metal structure 400.

As shown in FIG. 4D, regions 407 of the dye 404 incorporated into the outer anodized portion may be selectively altered. Bleached marking of the regions 407 may be used. Regions 407 of the dye may be selectively altered so as to have an appearance that is substantially lighter than remainder unaltered regions of the dye 404. Selectively altered regions 407 of the dye may be arranged in a lightness halftone pattern. The selectively altered regions 407 of the dye may be laser bleached to provide predetermined marking of the electronic device housing. The selectively altered regions 407 of the dye may cause one or more textual or graphical indicia to appear on the metal structure 400 of the electronic device housing.

The altered regions 407 of the dye 404 can be formed within the anodized outer portion 402 by a laser output 408 through the anodized outer portion 402. An ultraviolet laser 410 can be used for generating the laser output 408. Laser 410 may include a galvanometer mirror or other arrangement for raster scanning a spot of optical energy over the inner anodized surface 402, so as to form the selectively altered regions 407 into a rasterized depiction of the marking indicia. Suitable pitch between raster scan lines of the scanning spot may be selected.

Laser bleaching may comprise scanning output 408 of the laser 410 over the anodized outer portion 402 sufficiently slowly so as to substantially avoid noticeable disturbance to the anodized outer portion 402. Output 408 of the laser 410 may be scanned sufficiently slowly over the anodized outer portion 402 so as to substantially avoid microcracking of the anodized outer portion 402. It is theorized that scanning sufficiently slowly may limit thermal stresses by slowing laser heating and/or slowing cooling after laser heating. It is theorized that limiting thermal stresses by avoiding heating or cooling too quicky may contribute to substantially avoiding microcracking of the anodized outer portion 402, or otherwise contribute to substantially avoiding noticeable disturbance to the anodized outer portion 402.

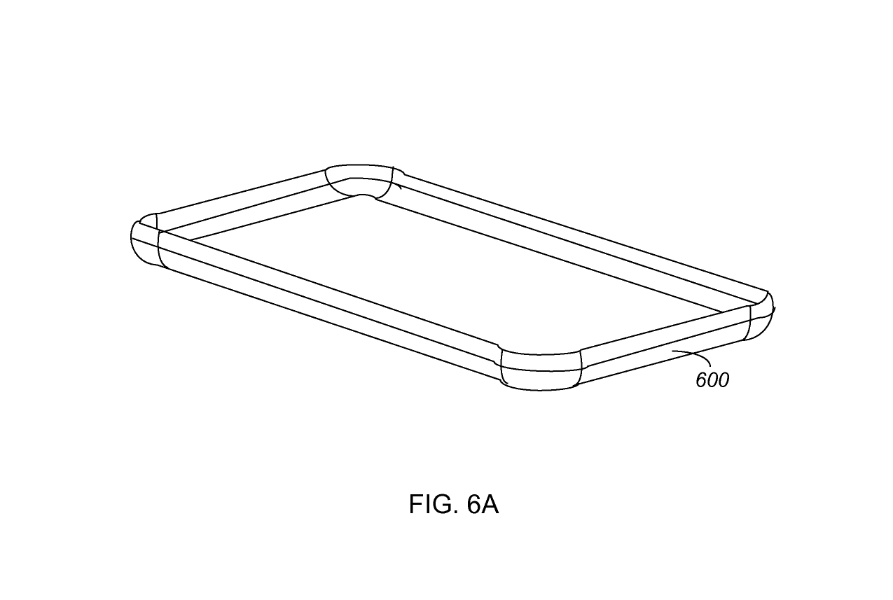

FIG. 5 is a table illustrating exemplary laser operation parameters for bleached marking of the dyed anodization of the metal structure. Columns of the table show laser operation parameters for bleaching Pink, Blue, Orange, Purple, and Green dyes. The table of FIG. 5 shows parameters for a FOBA model number DP2UV laser marking machine which is available from FOBA Technology and Services GmbH, having offices at 159 Swanson Road, Boxborough, Mass.

The FOBA DP2UV is a two watt ultraviolet laser marking machine, which has a laser output wave length of approximately three hundred and fifty five nanometers. Scanning spot size is estimated as approximately forty-five microns. As shown in the first row of the table, one hundred percent of the two watt power of the laser may be selected. Laser pulse repetition frequency of eighty kilohertz may be selected for the Pink dye. Laser pulse repetition of seventy-five kilohertz may be selected for the Blue, Orange, Purple, and Green dyes. Scan line spacing of ten microns may be selected.

The table of FIG. 5 illustrates exemplary laser operation parameters for marking according to one embodiment, wherein the laser is scanned over the anodized outer portion of the metal structure sufficiently slowly so as to substantially avoid noticeable disturbance to the anodized outer portion. Output of the laser may be scanned sufficiently slowly over the anodized outer portion so as to substantially avoid microcracking of the anodized outer portion. Further, different dyes, in particular differently colored dyes, may make differing contributions to heating and/or cooling of the anodized outer portion during laser bleaching. Accordingly, to substantially avoid microcracking of the anodized outer portion, or to otherwise substantially avoid noticeable disturbance to the anodized outer portion, differing scan speed limits may be employed for different dyes. For the Pink dye, scan speed of ninety millimeters per second may be selected. For the Blue dye, scan speed of seventy-five millimeters per second may be selected. For the Orange, Purple and Green dyes, scan speeds of fifty millimeters per second may be selected. It should be understood that the table of FIG. 5 shows approximate exemplary laser operating parameters, and that various other laser operating parameters may be selected to provide the bleached marking while substantially avoiding microcracking and/or noticeable disturbance to the anodized outer portion of the metal structure.

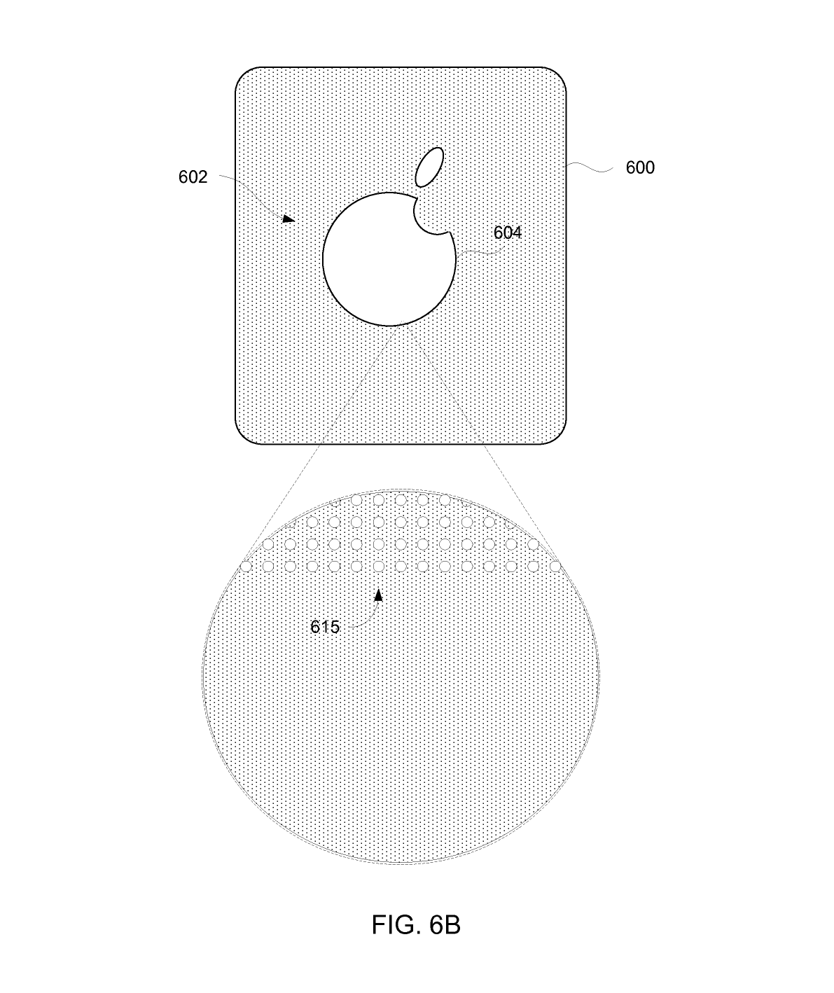

FIG. 6A is a diagrammatic representation of an exemplary product housing 600. The housing may be formed using metal. The housing 600 may be a housing that is to be a part of an overall assembly, as for example a bottom of a cell phone assembly or portable media player.

FIG. 6B illustrates the product housing 600 having markings 602 according to one exemplary embodiment. In this example, the labeling includes a logo graphic 604. The markings 602 can be bleached markings. Regions of the dye may be selectively altered so as to have an appearance that is substantially lighter than remainder unaltered regions of the dye.

Selectively altered regions of the dye may be arranged in a lightness halftone pattern. FIG. 6B further shows a detail magnified view, so as to show lightness halftone pattern 615. For purposes of illustration, FIG. 6 shows a number of bleached dots of the lightness halftone pattern 615 in magnified view. Size of the selectively bleached regions, as well as spaced apart arrangement of the selectively bleached regions in the lightness halftone pattern 615 may be selected so as to provide a desired lightness halftoning appearance.

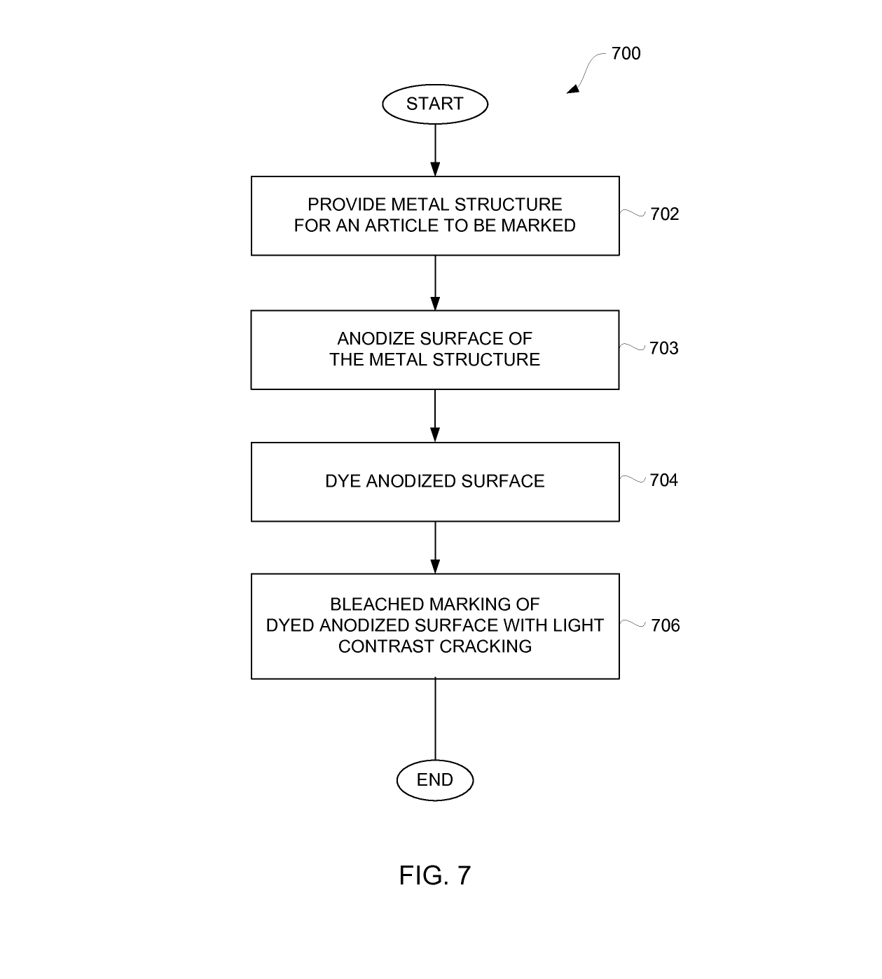

FIG. 7 is a flow diagram of a marking process 700 according to another embodiment. In accordance with the marking process 700 shown in FIG. 7, the process may begin with providing 702 the metal structure of the electronic device to be marked. After the metal structure has been provided 702, the surface of the metal structure may be anodized 703. Next, as shown in FIG. 7, the anodized surface of the metal structure may be dyed 704.

Next, regions of the dye incorporated into the outer anodized portion may be selectively altered. Bleached marking 706 may be used. Laser bleaching 706 may comprise scanning output of a laser over the anodized outer portion sufficiently quickly for substantially microcracking the anodized outer portion. The microcracking may scatter light for a white or light appearance. The microcracking may contribute to lightness contrast of the bleached regions relative to remainder unaltered regions of the dye. Following the bleached marking block 706, the marking process 700 shown in FIG. 7 can end.

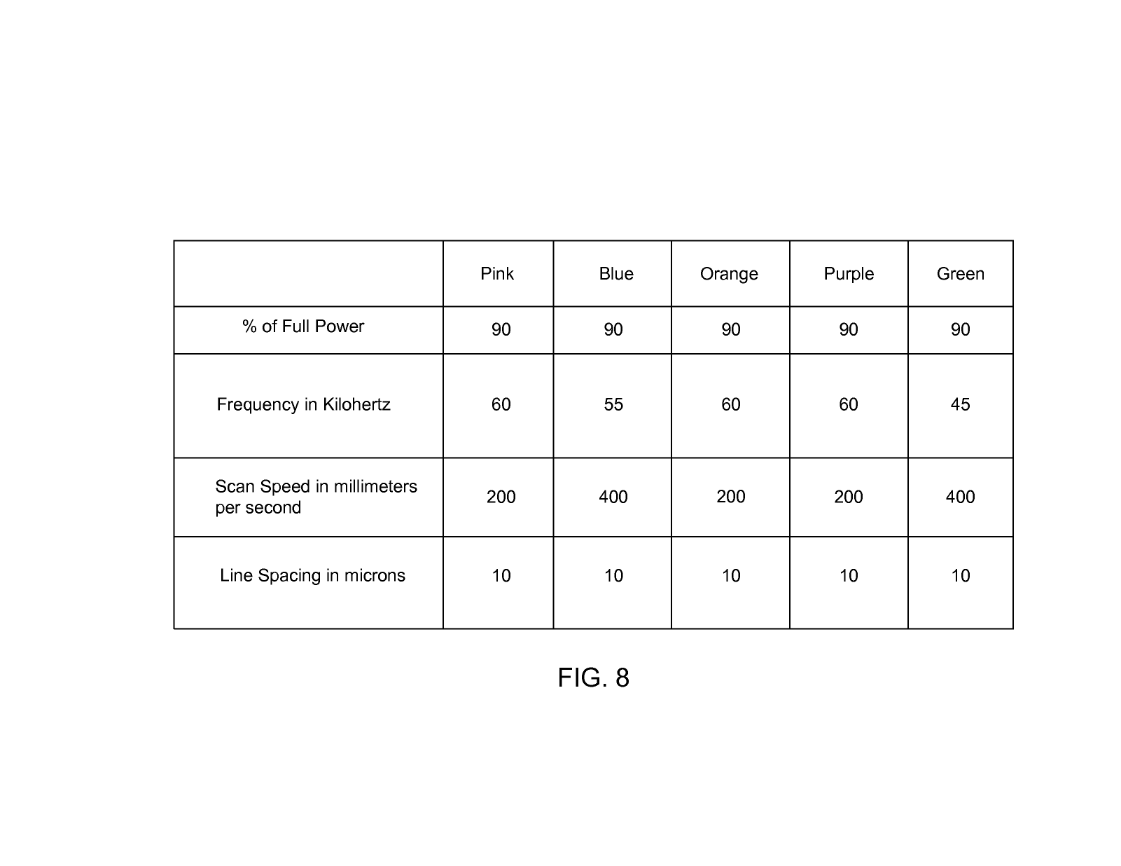

FIG. 8 is a second table illustrating exemplary laser operation parameters for marking according to another embodiment, as just discussed, wherein the laser is scanned over the anodized outer portion of the metal structure sufficiently quickly for substantially microcracking the anodized outer portion. Different dyes, in particular differently colored dyes, may make differing contributions to heating and/or cooling of the anodized outer portion during laser bleaching. Accordingly, for substantially microcracking of the anodized outer portion, differing scan speed limits may be employed for different dyes. For the Pink, Orange, and Purple dye, scan speed of two-hundred millimeters per second may be selected. For the Blue and green dyes, scan speed of four hundred millimeters per second may be selected.

As shown in the first row of the table of FIG. 8, ninety percent of the two watt power of the FOBA DP2UV ultraviolet laser marking machine may be selected. Laser pulse repetition frequency of sixty kilohertz may be selected for the Pink, Orange and Purple dyes. Laser pulse repetition of fifty-five kilohertz may be selected for the Blue dye. Laser pulse repetition of forty-five kilohertz may be selected for the Green dye. Scan line spacing of ten microns may be selected. It should be understood that the table of FIG. 5 shows approximate exemplary laser operating parameters, and that various other laser operating parameters may be selected for substantially microcracking of the anodized outer portion of the metal structure.

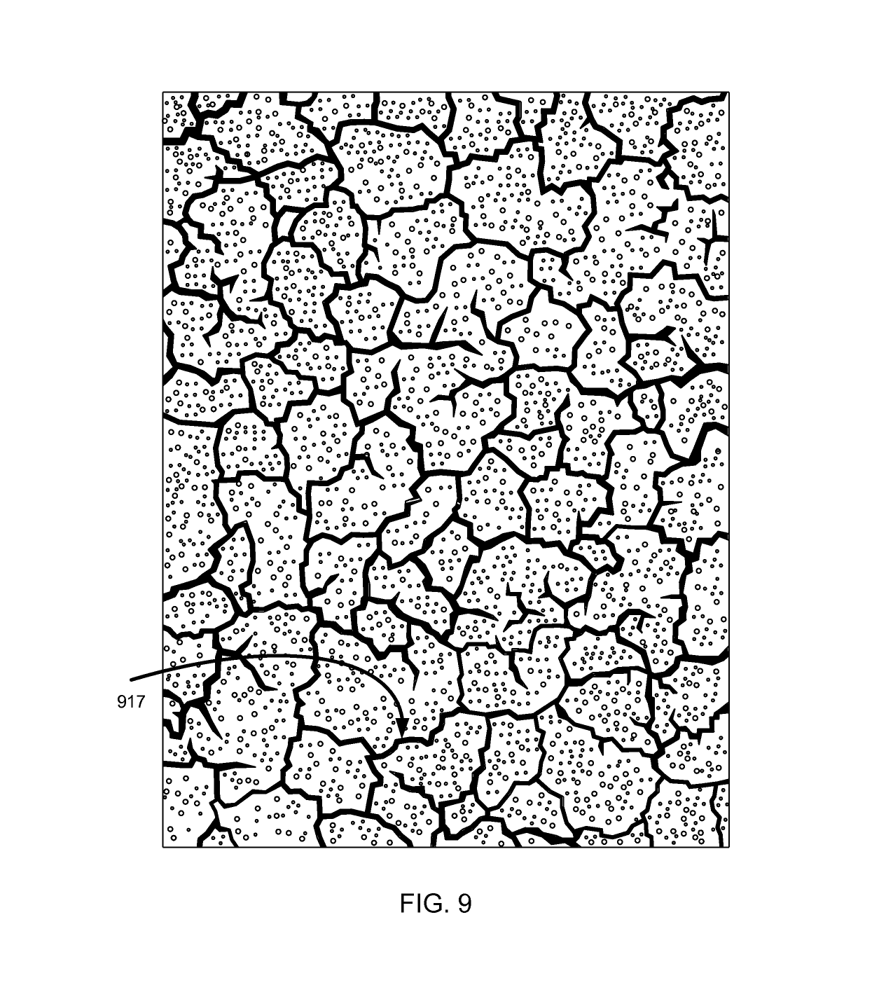

FIG. 9 is a top view diagram for representatively illustrating high magnification of microcracking 917 of the anodized outer portion of the metal structure. As mentioned previously herein, the anodized outer portion can be porous. Numerous pores having circular apertures are also depicted in FIG. 9.

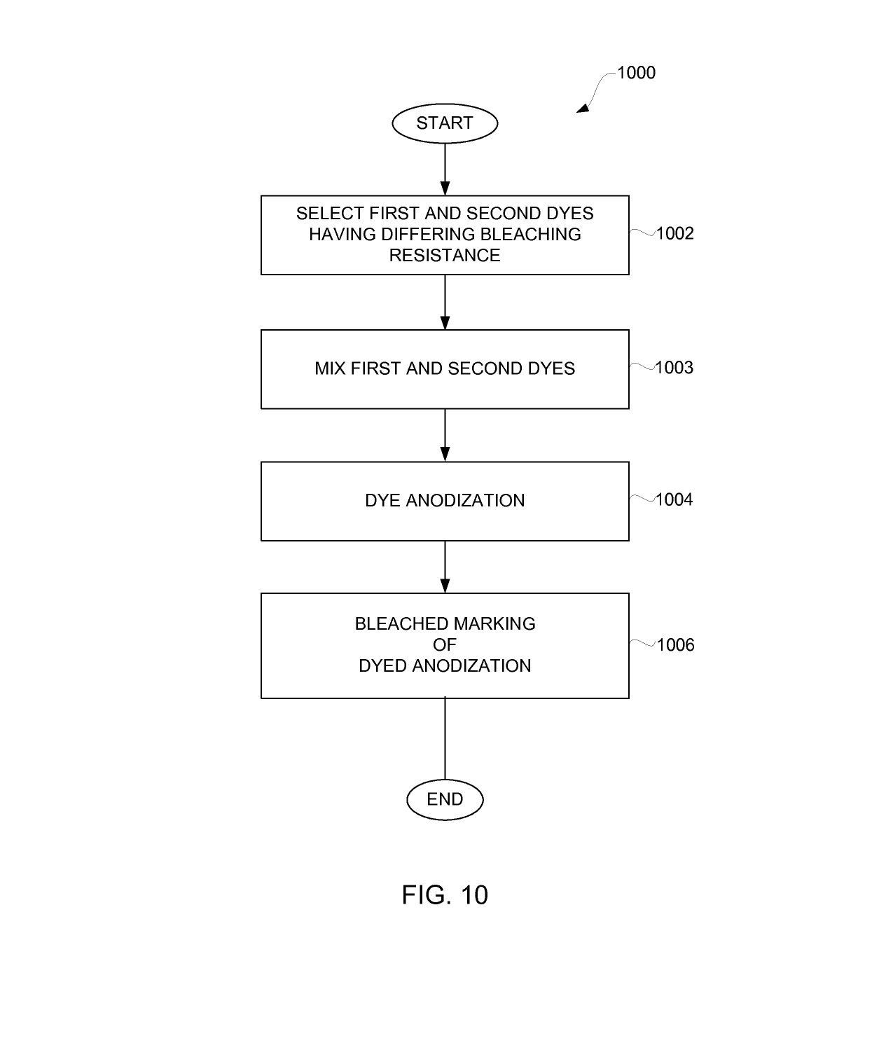

FIG. 10 is a flow diagram of a marking process 1000 according to another embodiment. The process 1000 may be used for marking an anodized metal structure of an article to be marked. The metal structure may have an anodized outer portion and an unanodized inner portion.

In accordance with the marking process 1000 shown in FIG. 10, the process may begin with selecting 1002 a first dye so as to have a first resistance to laser bleaching, and selecting 1002 a second dye so as to have a second resistance to laser bleaching . The first resistance to laser bleaching of the first dye can be substantially different than the second resistance to laser bleaching of the second dye. The second resistance to laser bleaching of the second dye can be substantially greater than the first resistance to laser bleaching of the first dye. The first dye may be an organic dye. The second dye may be an organometallic dye.

Next the first and second dyes can be mixed 1003 for incorporation into the anodization of the article (i.e. for incorporation into the anodized outer portion of the metal structure). Next the anodization can be dyed 1004 with first and second dyes. For example, the first dye and second dye can be incorporated into the anodized outer portion, adjacent to the unanodized inner portion.

Next bleached marking 1006, for example laser bleached marking, can be applied to the dyed anodization for sufficiently altering regions of the first dye, so as to provide predetermined marking of the article. Sufficient laser power may be employed for substantially overcoming the first laser bleaching resistance of the first dye. Laser power may be limited for substantially avoiding overcoming the second laser bleaching resistance of the second dye. Following the bleached marking block 1006, the marking process 1000 shown in FIG. 10 can end.

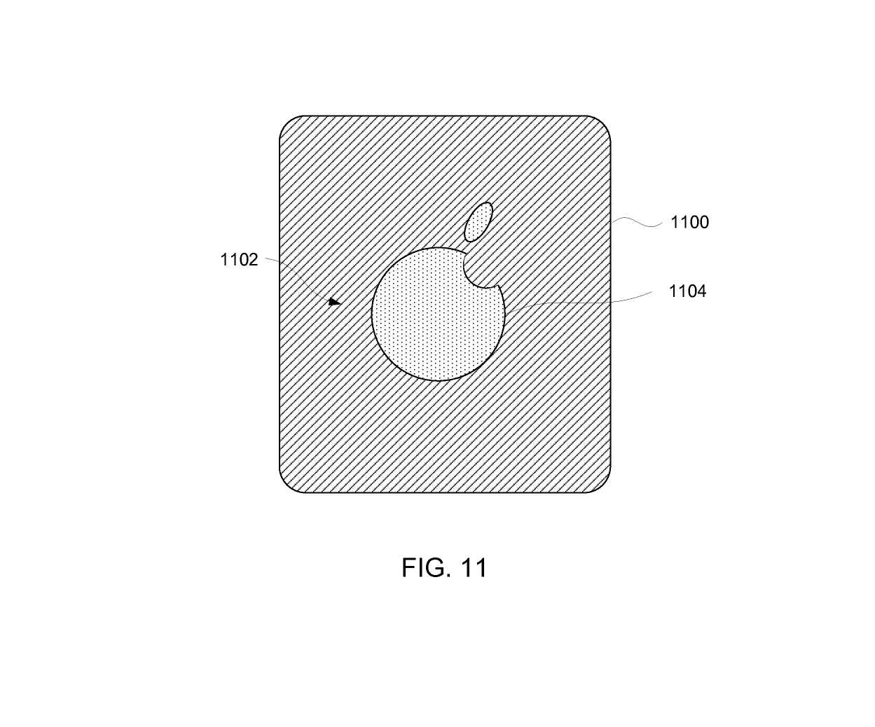

FIG. 11 illustrates product housing 1100 wherein anodization is dyed according to another embodiment using first and second dyes, as just discussed. The first dye can have a first resistance to laser bleaching. The second dye can have a second resistance to laser bleaching. The first resistance to laser bleaching of the first dye can be substantially different than the second resistance to laser bleaching of the second dye. The second resistance to laser bleaching of the second dye can be substantially greater than the first resistance to laser bleaching of the first dye. The first dye may be an organic dye. The second dye may be an organometallic dye.

FIG. 11 illustrates the product housing 1100 having markings 1102. In this example, the labeling includes a logo graphic 1104. The markings 1102 can be bleached markings.

Regions of the first dye may be selectively altered by laser bleaching so as to have an appearance that is substantially lighter than remainder unaltered regions of the first and second dyes. For the bleached marking, sufficient laser power may be employed for substantially overcoming the first laser bleaching resistance of the first dye. Laser power may be limited for substantially avoiding overcoming the second laser bleaching resistance of the second dye. Since the first dye may be substantially bleached away, while the second dye may remain substantially unbleached, the bleached region may retain an appearance of the second dye (shown with stippling in FIG. 11), while the remainder unaltered regions may have an appearance of the first and second dyes (shown with hatching in FIG. 11).

The marking processes described herein are, for example, suitable for applying text or graphics to a housing surface (e.g., an outer housing surface) of an electronic device. The marking processes are, in one embodiment, particularly well-suited for applying text and/or graphics to an outer housing surface of a portable electronic device. Examples of portable electronic devices include mobile telephones (e.g., cell phones), Personal Digital Assistants (PDAs), portable media players, remote controllers, pointing devices (e.g., computer mouse), game controllers, etc. The portable electronic device can further be a hand-held electronic device. The term hand-held generally means that the electronic device has a form factor that is small enough to be comfortably held in one hand. A hand-held electronic device may be directed at one-handed operation or two-handed operation. In one-handed operation, a single hand is used to both support the device as well as to perform operations with the user interface during use. In two-handed operation, one hand is used to support the device while the other hand performs operations with a user interface during use or alternatively both hands support the device as well as perform operations during use. In some cases, the hand-held electronic device is sized for placement into a pocket of the user. By being pocket-sized, the user does not have to directly carry the device and therefore the device can be taken almost anywhere the user travels (e.g., the user is not limited by carrying a large, bulky and often heavy device).

This application references: (i) U.S. patent application Ser. No. 13/021,641, filed Feb. 4, 2011, and entitled “Marking of Product Housings,” (ii) U.S. patent application Ser. No. 12/895,814, filed Sep. 30, 2010, and entitled “Sub-Surface Marking of Product Housings,” (iii) U.S. patent application Ser. No. 12/895,591, filed Sep. 30, 2010, and entitled “Cosmetic Conductive Laser Etching,” (iv) U.S. patent application Ser. No. 12/895,384, filed Sep. 30, 2010, and entitled “Sub-Surface Marking of Product Housings,” (v) U.S. patent application Ser. No. 12/643,772, filed Dec. 21, 2009, and entitled “Sub-Surface Marking of Product Housings,” (vi) U.S. patent application Ser. No. 12/569,810, filed Sep. 29, 2009, and entitled “Techniques for Marking Product Housings” which are hereby incorporated herein by reference.

The various aspects, features, embodiments or implementations of the invention described above can be used alone or in various combinations.

In general, the steps associated with the methods of the present invention may vary widely. Steps may be added, removed, altered, combined, and reordered without departing from the spirit or the scope of the present invention.

While this specification contains many specifics, these should not be construed as limitations on the scope of the disclosure or of what may be claimed, but rather as descriptions of features specific to particular embodiment of the disclosure. Certain features that are described in the context of separate embodiments may also be implemented in combination. Conversely, various features that are described in the context of a single embodiment may also be implemented in multiple embodiments separately or in any suitable subcombination. Moreover, although features may be described above as acting in certain combinations, one or more features from a claimed combination can in some cases be excised from the combination, and the claimed combination may be directed to a subcombination or variation of a subcombination.

Different aspects, embodiments or implementations may, but need not, yield one or more of the following advantages. One advantage of the invention is that durable, high precision markings can be provided to product housings. Another advantage of the invention is that bleached markings can have a distinctive appearance. Another advantage is that the marking techniques are effective for surfaces that are flat or curved.

The many features and advantages of the present invention are apparent from the written description. Further, since numerous modifications and changes will readily occur to those skilled in the art, the invention should not be limited to the exact construction and operation as illustrated and described. Hence, all suitable modifications and equivalents may be resorted to as falling within the scope of the invention.

What is claimed is:

1. An electronic device housing, comprising:
a metal structure of the electronic device housing including at least an outer portion and an inner portion, the outer portion being anodized and the inner portion being unanodized;
a first dye incorporated into the outer portion and adjacent to the inner portion; and
selectively altered regions of the first dye incorporated into the outer portion, wherein the altered regions of the first dye are laser bleached to provide predetermined marking of the electronic device housing.

2. An electronic device housing as recited in claim 1, wherein the altered regions of the first dye are formed within the outer portion adjacent to the inner portion after the outer portion has been anodized, and without substantially noticeable disturbance to the anodized outer portion.

3. An electronic device housing as recited in claim 1, wherein the altered regions of the first dye are formed within the outer portion adjacent to the inner portion after the outer portion has been anodized, and with substantial microcracking of the anodized outer portion.

4. An electronic device as recited in claim 1, wherein the altered regions of the first dye are formed within the outer portion by a laser output through the outer portion that has been anodized.

5. An electronic device as recited in claim 4, wherein the laser is an ultraviolet laser.

6. An electronic device as recited in claim 1, wherein the altered regions of the first dye cause one or more textual or graphical indicia to appear on the electronic device housing.

7. An electronic device as recited in claim 1, wherein the metal structure comprises aluminum.

8. An electronic device as recited in claim 1, wherein the selectively altered regions of the first dye have an appearance that is substantially lighter than remainder unaltered regions of the first dye.

9. An electronic device as recited in claim 8, wherein the selectively altered regions of the first dye are arranged in a lightness halftone pattern.

10. An electronic device as recited in claim 1, further comprising a second dye incorporated into the outer portion and adjacent to the inner portion.

11. An electronic device as recited in claim 10, wherein:
the first dye has a first laser bleaching resistance;
the second dye has a second laser bleaching resistance; and
the second laser bleaching resistance of the second dye is substantially greater than the first laser bleaching resistance of the first dye.

12. An electronic device as recited in claim 10, wherein:
the first dye comprises an organic dye; and
the second dye comprises an organometallic dye.

13. A method for marking an electronic device housing, comprising:
providing a metal structure for the electronic device housing;
anodizing an outer portion of the metal structure so as to provide an anodized outer portion of the metal structure and an unanodized inner portion of the metal structure;
incorporating a first dye into the outer portion and adjacent to the inner portion; and
selectively altering regions of the first dye incorporated into the outer portion, wherein the selectively altering comprises laser bleaching to provide predetermined marking of the electronic device housing.

14. A method as recited in claim 13, wherein laser bleaching comprises scanning output of a laser over the anodized outer portion sufficiently slowly so as to substantially avoid noticeable disturbance to the anodized outer portion.

15. A method as recited in claim 13, wherein laser bleaching comprises selectively scanning output of a laser over the anodized outer portion sufficiently slowly so as to substantially avoid microcracking of the anodized outer portion.

16. A method as recited in claim 13, wherein laser bleaching comprises selectively scanning output of a laser over the anodized outer portion sufficiently quickly for substantially microcracking the anodized outer portion.

17. A method as recited in claim 13, wherein laser bleaching comprises selectively scanning output of an ultraviolet laser over the anodized outer portion.

18. A method as recited in claim 13, wherein selectively altering regions of the first dye cause one or more textual or graphical indicia to appear on the electronic device housing.

19. A method as recited in claim 13, wherein the metal structure comprises aluminum.

20. A method as recited in claim 13, wherein selectively altering regions of the first dye comprise selectively altering regions of the first dye so as to have an appearance that is substantially lighter than remainder unaltered regions of the first dye.

21. A method as recited in claim 20, wherein selectively altering regions of the first dye further comprises arranging selectively altered regions of the first dye in a lightness halftone pattern.

22. A method for marking an article, comprising:
providing a metal structure for the article;
anodizing an outer portion of the metal structure so as to provide an anodized outer portion of the metal structure and an unanodized inner portion of the metal structure;
incorporating a first dye and a second dye into the outer portion, adjacent to the inner portion; and
sufficiently altering regions of the first dye so as to provide predetermined marking of the article.

23. A method as recited in claim 22 further comprising mixing the first dye and the second dye for incorporation into the outer portion.

24. A method as recited in claim 22 wherein sufficiently altering regions of the first dye comprises laser bleaching of the first dye.

25. A method as recited in claim 22 further comprising:
selecting the first dye so as to have a first resistance to laser bleaching; and
selecting the second dye so as to have a second resistance to laser bleaching, wherein the second resistance to laser bleaching of the second dye is substantially greater than the first resistance to laser bleaching of the first dye.

26. A method as recited in claim 21 wherein the first dye is an organic dye.

27. A method as recited in claim 21 wherein the second dye is an organometallic dye.
